(19) United States
(12) Patent Application Publication
(10) Pub. No.: US 2026/0188405 A1
(43) Pub. Date: Jul. 2, 2026

(54) DIE AND PLANE LEVEL FAILURE RECOVERY SCHEME

(71) Applicant: Sandisk Technologies, Inc., Milpitas, CA (US)

(72) Inventors: Niranjani Rajagopal, Tamil Nadu (IN); Jayavel Pachamuthu, San Jose, CA (US); Sowjanya Sunkavelli, Bengaluru (IN)

(21) Appl. No.: 19/005,223

(22) Filed: Dec. 30, 2024

(51) Int. Cl. G11C 29/12; G11C 29/44

(52) U.S. Cl. CPC G11C 29/12005; G11C 29/44

(57) ABSTRACT

A data storage device includes a memory die failure anticipation system that proactively determines when a plane of a memory die and/or the memory die itself, is likely to fail. To proactively determine whether the memory die is likely to fail, the memory die failure anticipation system periodically monitors performance characteristics of one or more voltage pumps of the memory die. If the memory die failure anticipation system determines, based on the performance characteristic(s), that the memory die is failing, the memory die failure anticipation system initiates a relocation operation that transfers data that is stored on the failing memory die to another memory die.

### BACKGROUND

Data storage devices are prone to various failures. In some examples, the failures are correctable. For example, data storage devices typically use error correction codes (ECCs) to fix bit errors that occur when data is written to and/or read from the data storage device. In other examples, one or more memory blocks of the data storage device may fail. In these examples, the data storage device may utilize bad block management and/or over-provisioning to help ensure that data stored on the failing blocks is relocated.

However, if a plane of a memory die of the data storage fails, or if the memory die itself fails, there is no recovery scheme that enables the data on the failed plane and/or on the memory die to be recovered. Such failures may occur due to fabrication process issues and/or due to normal wear and tear of the data storage device.

Accordingly, it would be beneficial to anticipate when a plane of a memory die, or the memory die itself, is likely to fail and take proactive steps to relocate the data to another plane and/or memory die of the data storage device.

### SUMMARY

The present disclosure describes a data storage device, such as a NAND data storage device, having a memory die failure anticipation system. The memory die failure anticipation system is configured to proactively determine when a plane of a memory die and/or the memory die itself, will fail. In an example, the failure may be the result of fabrication defects (e.g., due to material and/or fabrication variations) and/or from wear and tear caused by various stresses and/or program/erase (P/E) cycles.

To proactively determine whether a memory die (or a plane of a memory die) is failing or will fail, the memory die failure anticipation system tracks or periodically monitors performance characteristics of one or more voltage pumps of the memory die. For example, after a threshold number of P/E cycles have occurred, the memory die failure anticipation system determines a pump rate (or other performance characteristic(s) of one or more voltage pumps associated with a particular memory die) and determines, based, at least in part, on the performance characteristic(s), whether the memory die is failing or is likely to fail. If the memory die failure anticipation system determines, based on the performance characteristic(s), that the memory die is failing, the memory die failure anticipation system initiates a relocation operation that transfers data that is stored on the failing memory die to another memory die.

The relocation operation includes determining whether the data storage device has a sufficient number of available memory blocks for the relocation operation. If so, the memory die failure anticipation system causes data to be read from the failing memory die and also causes the read data to be written to the available memory blocks. The memory die failure anticipation system also updates various links to the new memory blocks and marks the old memory blocks associated with the failed memory die as grown bad blocks.

However, if the memory die failure anticipation system determines that there is not a sufficient number of available memory blocks for the relocation operation, the memory die failure anticipation system causes the data to be read from the failing memory die and writes the data to any available memory blocks. In an example, this includes writing the data to available single-level cell (SLC) memory blocks, but operating the SLC memory blocks in a multi-level cell (MLC) mode. Once the relocation operation is complete, the memory die failure anticipation system updates links associated with the memory blocks in a mapping table. The memory die failure anticipation system also causes the data storage device to enter a read-only mode.

Accordingly, examples of the present disclosure describe a method that includes determining at least one performance characteristic of at least one voltage pump of a memory device at a first instance. The at least one performance characteristic of the at least one voltage pump of the memory device is compared to a performance characteristic threshold. Based, at least in part, on determining the at least one performance characteristic of the at least one voltage pump of the memory device is below the performance characteristic threshold, the at least one performance characteristic of the at least one voltage pump of the memory device is determined at a second instance. The performance characteristic of the at least one voltage pump of the memory device at the first instance is compared to the performance characteristic of the at least one voltage pump of the memory device at the second instance. Based, at least in part, on the performance characteristic of the at least one voltage pump of the memory device at the first instance matching the performance characteristic of the at least one voltage pump of the memory device at the second instance, a plurality of memory blocks of the memory device associated with the at least one voltage pump are selected and each memory block of the plurality of memory blocks are erased. A status of each memory block of the plurality of memory blocks is determined. A determination is then made as to whether to initiate a relocation operation based, at least in part, on the determined status of each memory block of the plurality of memory blocks.

Examples of the present disclosure also describe a data storage device that includes a controller and a memory die failure anticipation system communicatively coupled to the controller. The memory die failure anticipation system is operable to periodically determine a first performance characteristic of at least one voltage pump associated with the data storage device and initiate a first memory die failure anticipation operation based, at least in part, on the first performance characteristic matching a second performance characteristic of the at least one voltage pump associated with the data storage device. The memory die failure anticipation system is also operable to initiate a second memory die failure anticipation operation based, at least in part, on the first performance characteristic being different than the second performance characteristic.

Still other examples describe a data storage device having a means for determining a performance characteristic of at least one voltage supply means associated with the data storage device and a means for comparing the performance characteristic of the at least one voltage supply means to a performance characteristic threshold. The data storage device also includes a means for determining whether multiple memory blocks associated with the voltage supply means have failed. In an example, the means for determining whether the multiple memory blocks associated with the voltage supply means has failed makes the determination based, at least in part, on the comparing the performance characteristic of the at least one voltage supply means to the performance characteristic threshold. The data storage device also includes means for initiating a relocation operation. In an example, the means for initiating the relocation operation initiates the relocation operation based, at least in part, on the means for determining whether multiple memory blocks associated with the voltage supply means determines that multiple memory blocks have failed.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a block diagram of a system that includes a host device and a data storage device according to an example.

FIG. 2A illustrates how a memory die includes a number of memory blocks according to an example.

FIG. 2B illustrates how a memory block includes one or more pages according to an example.

FIG. 3 illustrates a method for identifying memory dies that are failing and/or are likely to fail based on determined performance characteristics of a voltage pump according to an example.

FIG. 4 illustrates a method for determining whether a memory die is failing according to an example.

FIG. 5 illustrates a method for determining whether a memory die is failing according to another example.

FIG. 6 illustrates a first relocation operation according to an example.

FIG. 7 illustrates a second relocation operation according to an example.

FIG. 8 is a perspective view of a storage device that includes three-dimensional (3D) stacked non-volatile memory according to an example.

FIG. 9 is a block diagram of a storage device according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

As previously described, data storage devices are prone to various failures. While some of these failures are correctable, others are not. For example, error correction codes (ECCs) may be used to fix bit errors that occur when data is written to and/or read from the data storage device. In other examples, bad block management and/or over-provisioning operations help ensure that data stored on a failing memory block is relocated.

However, there is no way to recover data from a memory die if a plane of the memory die fails and/or if the memory die itself fails. Thus, if a plane of the memory die fails and/or the memory die itself fails, the data is lost.

To address this, the present disclosure describes a data storage device having a memory die failure anticipation system. The memory die failure anticipation system is operable to proactively determine when a plane of a memory die and/or the memory die itself, is failing and/or is likely to fail.

To proactively determine whether the memory die (or whether a plane of the memory die) is failing or is likely to fail, the memory die failure anticipation system tracks, or periodically monitors one or more performance characteristics of one or more voltage pumps associated with a memory die. For example, after a threshold number of P/E cycles have occurred, the memory die failure anticipation system determines a pump rate (or other performance characteristic(s) of one or more voltage pumps associated with a particular memory die). In an example, the performance characteristic (also referred to as a first performance characteristic) of the one or more voltage pumps of the memory die is determined at a first instance (e.g., when the particular voltage pump is disconnected or isolated from an array of memory cells of the memory die).

If the first performance characteristic is below a performance threshold, the performance characteristic of the particular voltage pump is determined at a second instance (also referred to as a second performance characteristic). In an example, the second instance is at a second time or a second configuration (e.g., when the particular voltage pump is connected to the array of memory cells).

If the first performance characteristic taken at the first instance matches the second performance characteristic taken at the second instance, the memory die failure anticipation system determines whether a single memory block has grown bad or whether multiple memory blocks have gone bad (thereby indicating that the memory die (or a plane) is failing). If the memory die failure anticipation system determines the memory die is failing, the memory die failure anticipation system initiates a relocation operation that transfers data that is stored on the failing memory die to another memory die.

As will be explained in greater detail herein, the relocation operation includes determining whether the data storage device has a sufficient number of spare/available memory blocks for the relocation operation. If so, the memory die failure anticipation system causes data to be read from the failing memory die and also causes the read data to be written to the available memory blocks. The memory die failure anticipation system also updates various links to the new memory blocks and marks the memory blocks associated with the failed memory die as grown bad blocks.

However, if the memory die failure anticipation system determines that there is not a sufficient number of spare/available memory blocks for the relocation operation, the memory die failure anticipation system causes the data to be read from the failing memory die and writes the data to any available memory blocks. In an example, this includes writing the data to all single-level cell (SLC) memory blocks but operating the SLC memory blocks in a multi-level cell (MLC) mode. Once the relocation operation is complete, the memory die failure anticipation system updates links in a mapping table. The memory die failure anticipation system also causes the data storage device to enter a read-only mode.

In accordance with the above, many technical benefits may be realized including, but not limited to, reducing or eliminating the risk of data loss and/or corruption due to failing planes and/or failing memory dies, and increasing a reliability of the data storage device by proactively identifying memory dies that will grow bad and retiring the memory dies before data becomes lost.

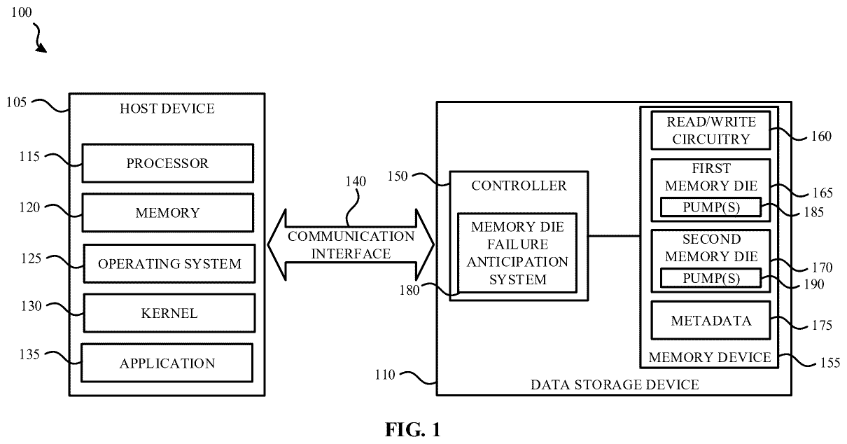

These benefits, along with other examples, will be shown and described in greater detail with respect to FIG. 1-FIG. 9.

FIG. 1 is a block diagram of a system 100 that includes a host device 105 and a data storage device 110 according to an example. In an example, the host device 105 includes a processor 115 and a memory 120 (e.g., main memory). The memory 120 may include or otherwise be associated with an operating system 125, a kernel 130 and/or an application 135.

The processor 115 executes various instructions, such as, for example, instructions from the operating system 125 and/or the application 135. The processor 115 may include circuitry such as a microcontroller, a Digital Signal Processor (DSP), an Application-Specific Integrated Circuit (ASIC), a Field Programmable Gate Array (FPGA), hard-wired logic, analog circuitry and/or various combinations thereof. In an example, the processor 115 may include a System on a Chip (SoC).

In an example, the memory 120 can be used by the host device 105 to store data. The data that is used, or executed by, the processor 115. Data stored in the memory 120 may include instructions provided by the data storage device 110 via a communication interface 140. The data stored in the memory 120 may also include data used to execute instructions from the operating system 125 and/or one or more applications 135. The memory 120 may be a single memory or may include multiple memories, such as, for example one or more non-volatile memories, one or more volatile memories, or a combination thereof.

In an example, the operating system 125 may create a virtual address space for the application 135 and/or other processes executed by the processor 115. The virtual address space may map to locations in the memory 120. The operating system 125 may also include or otherwise be associated with a kernel 130. The kernel 130 may include instructions for managing various resources of the host device 105 (e.g., memory allocation), handling read and write requests and so on.

The communication interface 140 communicatively couples the host device 105 and the data storage device 110. The communication interface 140 may be a Serial Advanced Technology Attachment (SATA), a PCI express (PCIe) bus, a Small Computer System Interface (SCSI), a Serial Attached SCSI (SAS), Ethernet, Fibre Channel, or Wi-Fi. As such, the host device 105 and the data storage device 110 need not be physically co-located and may communicate over a network such as a Local Area Network (LAN) or a Wide Area Network (WAN), such as the internet. In addition, the host device 105 may interface with the data storage device 110 using a logical interface specification such as Non-Volatile Memory express (NVMe) or Advanced Host Controller Interface (AHCI).

The data storage device 110 includes a controller 150 and a memory device 155. In an example, the controller 150 is communicatively coupled to the memory device 155. In an example, the memory device 155 includes one or more memory dies (e.g., first memory die 165 and second memory die 170). Although memory dies are specifically mentioned, the memory device 155 may include any non-volatile memory device, storage device, storage elements or storage medium including NAND flash memory cells and/or NOR flash memory cells.

The memory cells can take the form of solid-state (e.g., flash) memory cells and can be one-time programmable, few-times programmable, or many-times programmable. Additionally, the memory cells may be single-level cells (SLCs), multi-level cells (MLCs), triple-level cells (TLCs), quad-level cells (QLCs), penta-level cells (PLCs), and/or use any other memory technologies. The memory cells may be arranged in a two-dimensional configuration or a three-dimensional configuration.

In an example, the data storage device 110 is attached to or embedded within the host device 105. In another example, the data storage device 110 is implemented as an external device or a portable device that can be communicatively or selectively coupled to the host device 105. In yet another example, the data storage device 110 is a component (e.g., a solid-state drive (SSD)) of a network accessible data storage system, a network-attached storage system, a cloud data storage system, or the like.

As indicated above, the memory device 155 of the data storage device 110 includes a first memory die 165 and a second memory die 170. Although two memory dies are shown, the memory device 155 may include any number of memory dies (e.g., one memory die, two memory dies, eight memory dies, or another number of memory dies).

In an example, each memory die includes or is otherwise associated with one or more voltage pumps. For example, the first memory die 165 includes voltage pumps 185 and the second memory die 170 includes voltage pumps 190. In examples in which the memory dies include multiple voltage pumps, at least one voltage pump is associated and/or shared across all of the planes of the memory dies and at least one voltage pump is associated with a respective plane of the memory die.

For example, each memory die includes a first voltage pump (e.g., a UMSYS voltage pump) and a second voltage pump (e.g., a VMSYS voltage pump). For example, the first voltage pump is associated with a first type of voltage signals (e.g., VPGM and/or a VERA voltage pump signals) and is shared across all of the planes of the memory die. In another example, the second voltage pump is associated with a second type of signal (e.g., a VREAD pump signal) and is not shared across all of the planes of the memory die. Rather, the second voltage pump is specific to a particular plane of the memory die.

As will be explained in greater detail herein, when the performance characteristic(s) of the first voltage pump (and/or the one or more pump signals associated with the first voltage pump) are determined, the performance characteristics may indicate that a particular memory die (e.g., the first memory die 165) is failing or is likely to fail. However, when the performance characteristic(s) of the second voltage pump are determined, the performance characteristic(s) of the second voltage pump (and/or the voltage pump signal associated with the second voltage pump) may indicate that a particular plane of the memory die (e.g., a first plane of the first memory die 165) is failing or is likely to fail.

The memory device 155 also includes support circuitry. In an example, the support circuitry includes read/write circuitry 160. The read/write circuitry 160 supports the operation of the memory dies of the memory device 155. Although the read/write circuitry 160 is depicted as a single component, the read/write circuitry 160 may be divided into separate components, such as, for example, read circuitry and write circuitry. The read/write circuitry 160 may be external to the memory dies of the memory device 155. In another example, one or more of the memory dies may include corresponding read/write circuitry 160 that is operable to read data from and/or write data to storage elements within one individual memory die independent of other read and/or write operations on any of the other memory dies.

In an example, one or more of the first memory die 165 and the second memory die 170 include one or more planes and each plane may have one or more memory blocks. In an example, each memory block includes one or more memory cells. A block of memory cells is the smallest number of memory cells that are physically erasable together. In an example and for increased parallelism, each of the blocks may be operated or organized in larger blocks or metablocks. For example, one block from different planes of memory cells may be logically linked together to form a metablock.

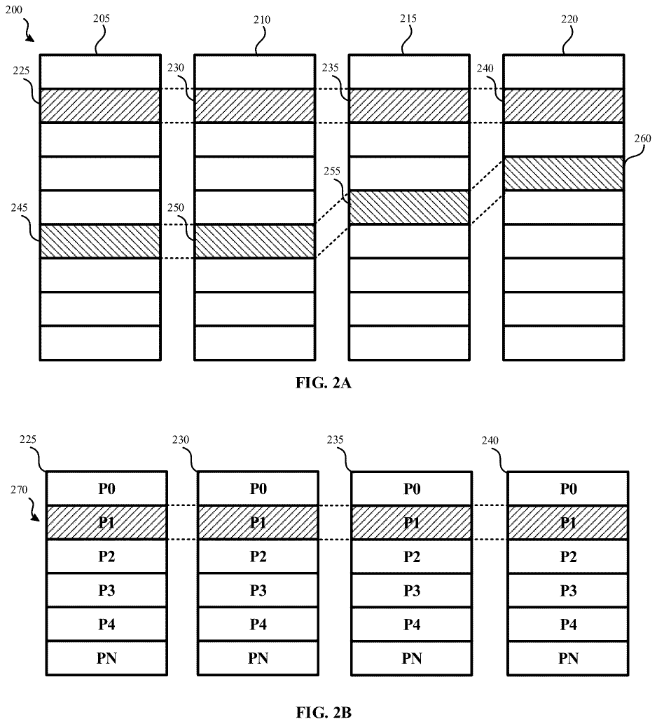

For example and referring to FIG. 2A, a memory device 200 (e.g., a storage element, a memory die, a non-volatile memory device) includes four planes or sub-arrays (e.g., a first plane 205, a second plane 210, a third plane 215, and a fourth plane 220). In an example, the planes are integrated on a single memory die, are provided on two different memory dies (e.g., two planes on each memory die) or are provided on four separate memory dies. Although four planes are shown and described, the memory device 200 may have any number of planes and/or memory dies.

Additionally, and as previously described, voltage pumps may be associated with the memory device 200. For example, one or more voltage pumps may be shared across each of the four planes while one or more voltage pumps may be associated with a single plane.

In an example, the planes are divided into memory blocks consisting of memory cells. As shown in FIG. 2A, the rectangles represent each memory block, such as memory block 225, memory block 230, memory block 235 and memory block 240. There may be dozens or hundreds of memory blocks in each plane of the memory device 200. In an example, each memory block is a unit of erase and is sometimes referred to as an erase block. For example, memory block 225, memory block 230, memory block 235 and memory block 240 include a minimum number of memory cells that are erased together.

In addition, various memory blocks may be logically linked or grouped together (e.g., using a table in or otherwise accessible by the controller 150) to form a metablock. A metablock may be written to, read from and/or erased as a single unit. For example, memory block 225, memory block 230, memory block 235 and memory block 240 may form a first metablock while memory block 245, memory block 250, memory block 255 and memory block 260 may form a second metablock. The memory blocks used to form a metablock need not be restricted to the same relative locations within their respective planes.

In an example, each memory block may be divided, for operational purposes, into pages of memory cells, such as illustrated in FIG. 2B. For example, the memory cells of memory block 225, memory block 230, memory block 235 and memory block 240 are divided into N different pages (shown as P0-PN). Although a specific number of pages are shown in FIG. 2B, a memory block may have any number of pages of memory cells within each memory block.

In an example, a page is a unit of data programming within the memory block. Each page includes the minimum amount of data that can be programmed at one time. The minimum unit of data that can be read at one time may be less than a page. A metapage 270 is illustrated in FIG. 2B as being formed of one physical page from memory block 225, memory block 230, memory block 235 and memory block 240. In the example, shown, the metapage 270 includes page P1 in each of the four memory blocks. However, the pages of the metapage 270 need not have the same relative position within each of the memory blocks. A metapage 270 may be the maximum unit of programming within a memory block.

The memory blocks disclosed in FIG. 2A-FIG. 2B are referred to herein as physical memory blocks because they relate to groups of physical memory cells. As used herein, a logical memory block is a virtual unit of address space defined to have the same size as a physical memory block. Each logical memory block includes a range of logical memory block addresses (LBAs) that are associated with data received from a host. The LBAs are then mapped to one or more physical memory blocks in the data storage device 110 where the data is physically stored.

As indicated above, each memory block may include any number of memory cells. The design, size, and organization of a memory block may depend on the architecture, design, and application desired for each memory die. In an example, the memory block includes a contiguous set of memory cells that share a plurality of wordlines and bit lines. A wordline may function as a single-level-cell (SLC) wordline, a multi-level-cell (MLC) wordline, a tri-level-cell (TLC) wordline, a quad-level cell (QLC) wordline, a penta-level cell (PLC) wordline and so on. Additionally, each memory cell may be programmable to a state (e.g., a threshold voltage in a flash configuration or a resistive state in a resistive memory configuration) that indicates one or more values.

As previously described, the data storage device 110 also include a controller 150. Although a single controller 150 is shown, the data storage device 110 can include multiple controllers. In such an example, a first controller executes a first number and/or type of commands while a second controller executes a second number and/or type of commands. The controllers may operate in parallel and/or independently.

The controller 150 is communicatively coupled to the memory device 155 via a bus, an interface or other communication circuitry. In an example, the communication circuitry may include one or more channels to enable the controller 150 to communicate with the first memory die 165 and/or the second memory die 170 of the memory device 155. In another example, the communication circuitry may include multiple distinct channels which enables the controller 150 to communicate with the first memory die 165 independently and/or in parallel with the second memory die 170 of the memory device 155.

The controller 150 receives data and/or instructions from the host device 105. The controller 150 also sends data to the host device 105. For example, the controller 150 sends data to and/or receives data from the host device 105 via the communication interface 140. The controller 150 also sends data and/or commands to, and/or receive data from, the memory device 155.

The controller 150 sends data and a corresponding write command to the memory device 155 to cause the memory device 155 to store data at a specified address of the memory device 155. In an example, the write command specifies a physical address of a portion of the memory device 155.

The controller 150 also sends data and/or commands associated with one or more background scanning operations, garbage collection operations, and/or wear leveling operations. The controller 150 also sends one or more read commands to the memory device 155. In an example, the read command specifies the physical address of a portion of the memory device 155 at which the data is stored. The controller 150 may also track the number of program/erase cycles or other programming operations that have been performed on or by the memory device 155 and/or on or by the memory dies of the memory device 155.

The controller 150 also includes, or is otherwise associated with, a memory die failure anticipation system 180. In an example, the memory die failure anticipation system 180 is a packaged functional hardware unit designed for use with other components/systems. In another example, the memory die failure anticipation system 180 is a portion of a program code (e.g., software or firmware) executable by a processor or processing circuitry. In yet another example, the memory die failure anticipation system 180 is a self-contained hardware and/or software component that interfaces with other components and/or systems. Although the memory die failure anticipation system 180 is shown as being part of the controller 150, the memory die failure anticipation system 180 may be separate from the controller 150.

In an example, the memory die failure anticipation system 180 is operable, along with the controller 150, to determine whether one or more planes of one or more of the memory dies, and/or whether one or more memory dies, are failing and/or are likely to fail. In an example, the memory die failure anticipation system 180 determines whether one or more of the memory dies is failing or is likely to fail based, at least in part, on monitoring and/or determining one or more performance characteristics of the voltage pumps associated with each of the memory dies.

For example, during a program and/or an erase operation, the voltage pump(s) 185 of the first memory die 165 and/or the voltage pump(s) 190 of the second memory die 170 should reach a target voltage threshold (e.g., at least fifteen volts). However, if one or more of the voltage pumps are not reaching the target voltage threshold, the memory die and/or a plane of the memory die (depending on the voltage pump(s) being monitored) may be failing or may be likely to fail.

As such, in effort to anticipate a voltage pump failure, a plane failure and/or a memory die failure, the memory die failure anticipation system 180 periodically monitors one or more performance characteristics of one or more of the voltage pumps of each memory die. In an example, the memory die failure anticipation system 180 monitors or determines the one or more performance characteristics based on a particular frequency (e.g., after a particular number of P/E cycles have occurred).

For example, the memory die failure anticipation system 180 determines the performance characteristics of one or more of the voltage pumps every one-thousand P/E cycles, every five-thousand P/E cycles, every seven-thousand P/E cycles and so on. Although a specific number of P/E cycles have been mentioned, the memory die failure anticipation system 180 may determine the performance characteristics of a particular voltage pump associated with a particular memory die and/or plane of the memory die after any number of P/E cycles have occurred. In an example, the number of P/E cycles is dynamic and/or is based, at least in part, on an age and/or a type/quality of the memory die. In another example, the number of P/E cycles static and/or predetermined.

In an example, the memory die failure anticipation system 180 determines the one or more performance characteristics (also referred to a first performance characteristic) of a particular voltage pump at a first instance or at a first time. In an example, the first instance is when the particular voltage pump is disconnected and/or isolated from the memory cells (or a NAND array) of the memory die.

In an example, the first performance characteristic is a voltage (or a voltage signal) that is supplied to memory die and/or a plane of the memory die. In another example, the first performance characteristic is a clock count associated with the voltage pump. In yet another example, the first performance characteristic of the voltage pump is a pump rate. Although specific performance characteristics are mentioned, other performance characteristics may be used.

When the first performance characteristic has been determined, the memory die failure anticipation system 180 compares the first performance characteristic to a performance characteristic threshold. If the memory die failure anticipation system 180 determines, based at least in part on the comparison, that the first performance characteristic meets or exceeds the performance characteristic threshold, the memory die failure anticipation system 180 may determine that the memory die and/or the voltage pump is functioning and/or performing as expected. As such, nothing else will be done until another series of P/E cycles have been performed.

However, if the memory die failure anticipation system 180 determines, based at least in part on the comparison, that the first performance characteristic falls below the performance characteristic threshold, the memory die failure anticipation system 180 is operable to determine whether the memory die is failing and/or is likely to fail.

To determine this, the memory die failure anticipation system 180 determines the performance characteristics of the voltage pump at a second instance and/or at a second time. In the examples that follow, the performance characteristic that is determined and/or monitored at the second instance is referred to as a second performance characteristic. In an example, the second instance is when the voltage pump is connected to the memory cells of the memory die.

The memory die failure anticipation system 180 then determines whether the first performance characteristic of the voltage pump at the first instance matches the second performance characteristic of the voltage pump at the second instance. For example, if the performance characteristic is a pump rate, the memory die failure anticipation system 180 checks the pump rate of the voltage pump when the voltage pump is isolated from the memory cells (e.g., using a clock count method) and also checks the pump rate of the voltage pump when the voltage pump is connected to the memory cells. The memory die failure anticipation system 180 then determines whether the total number of clock counts determined in the first instance matches the total number of clock counts determined in the second instance.

If the memory die failure anticipation system 180 determines that the first performance characteristic associated with the first instance matches the second performance characteristic of the second instance, the memory die failure anticipation system 180 determines whether to initiate a relocation operation.

When determining whether to initiate the relocation operation, the memory die failure anticipation system 180 determines whether one memory block of the memory die has grown bad or whether the memory die and/or the memory plane of the memory die is failing or is likely to fail. To determine this, the memory die failure anticipation system 180 selects multiple memory blocks of the memory die (e.g., multiple memory blocks of the first memory die 165). In an example, the memory blocks are randomly selected. Each of the selected memory blocks are erased and the memory die failure anticipation system 180 determines a status of each memory block (e.g., whether the memory block whether a single memory block has failed or whether multiple memory blocks have failed). In an example, the status of each memory block may be based, at least in part, on the voltage signals (e.g., read voltage signals and/or program voltage signals) that are being monitored. For example, if the voltage signal applied to the memory block is below the threshold, the memory block may have failed. In other examples, other failure detection mechanisms may be used.

If the memory die failure anticipation system 180 determines that a single memory block has failed, the memory die failure anticipation system 180 marks the single memory block as a grown bad block. The memory die failure anticipation system 180 may then repeat the operations previously described based on the determined frequency.

However, if the memory die failure anticipation system 180 determines that multiple memory blocks of the memory die have failed, the memory die failure anticipation system 180 may determine that the memory die and/or the plane of the memory die is failing or is likely to fail (and/or the one or more voltage pumps associated with the memory die is failing or is likely to fail). As such, the memory die failure anticipation system 180 initiates a relocation operation. In an example, and depending on the number of available memory blocks in the memory device 150, the memory die failure anticipation system 180 may initiate different relocation operations.

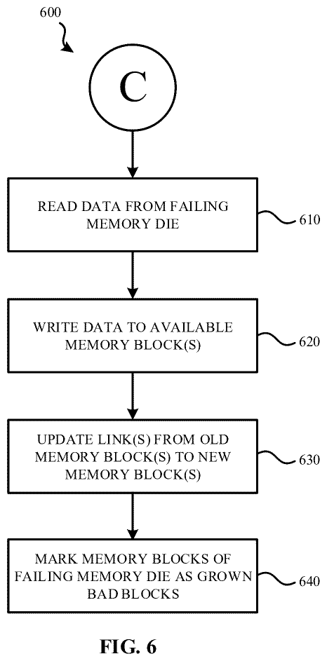

For example, if the number of available memory blocks in the memory device 150 exceeds a particular threshold, or if the memory die failure anticipation system 180 determines that the data storage device 110 (or the memory device 155) has a sufficient amount of memory blocks, a first relocation operation will be initiated by the memory die failure anticipation system 180. The first relocation operation is described in more detail with respect to FIG. 6.

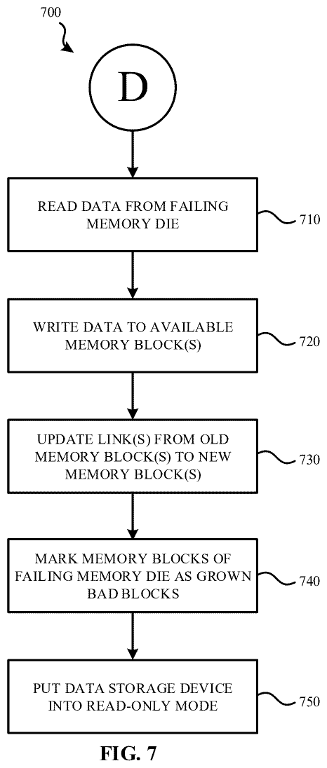

However, if the number of available memory blocks in the memory device 150 is below a particular threshold, or if the memory die failure anticipation system 180 determines that the data storage device 110 (or the memory device 155) does not have a sufficient amount of memory blocks, a second relocation operation will be initiated by the memory die failure anticipation system 180. The second relocation operation is described in more detail with respect to FIG. 7.

In an example and as used herein, the term “sufficient” means that the data storage device has enough space in one or more healthy memory dies and/or memory blocks to store all of the data that will be relocated from a failing memory die and/or from a failing plane of a memory die.

In another example, the memory die failure anticipation system 180 may determine that the first performance characteristic associated with the first instance do not match the second performance characteristic of the second instance. However, in an example, and even though the first performance characteristic does not match the second performance characteristic, the memory die failure anticipation system 180 may still determine whether to initiate a relocation operation.

When determining whether to initiate the relocation operation when the first performance characteristic associated with the first instance does not match the second performance characteristic of the second instance, the memory die failure anticipation system 180 determines whether one memory block of the particular memory die (e.g., the first memory die 165) has grown bad or whether the memory die and/or the memory plane of the memory die is failing or is likely to fail.

To determine this, the memory die failure anticipation system 180 selects (e.g., randomly selects) one or more memory blocks across different planes of the memory die. The memory die failure anticipation system 180 erases each of the selected memory blocks and determines a failed bit count (FBC) of each memory block. If the memory die failure anticipation system 180 determines that the FBC of a particular memory block exceeds a FBC threshold, the memory die failure anticipation system 180 increases a voltage level (e.g., a read voltage level and/or a program voltage) that is provided by the voltage pump associated with each memory block having a FBC over the FBC threshold.

If the FBC of a single memory block increases, the memory die failure anticipation system 180 marks that particular memory block as a grown bad block. The memory die failure anticipation system 180 may then repeat the operations previously described.

However, if the FBC of multiple memory blocks increases as the applied voltage (e.g., a read voltage) increases, the memory die and/or the plane of the memory die may be failing or likely to fail. As such, the memory die failure anticipation system 180 initiates a relocation operation. In an example, and depending on the number of available memory blocks in the memory device 150, the memory die failure anticipation system 180 may initiate different relocation operations.

For example, if the number of available memory blocks in the memory device 150 exceeds a particular threshold, or if the memory die failure anticipation system 180 determines that the data storage device 110 (or the memory device 155) has a sufficient amount of memory blocks, a first relocation operation will be initiated by the memory die failure anticipation system 180. The first relocation operation is described in more detail with respect to FIG. 6. However, if the number of available memory blocks in the memory device 150 is below a particular threshold, or if the memory die failure anticipation system 180 determines that the data storage device 110 (or the memory device 155) does not have a sufficient amount of memory blocks, a second relocation operation will be initiated by the memory die failure anticipation system 180. The second relocation operation is described in more detail with respect to FIG. 7.

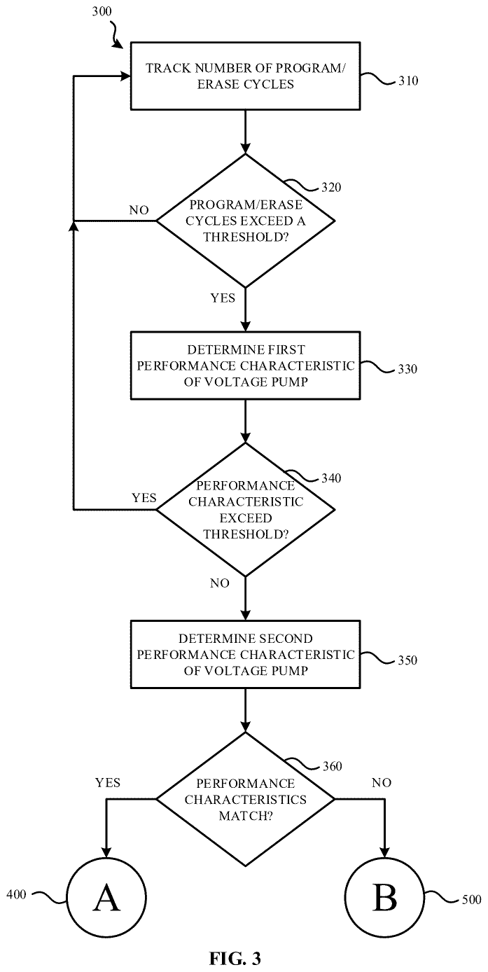

FIG. 3 illustrates a method 300 for identifying memory dies that are failing and/or are likely to fail based on determined performance characteristics of a voltage pump according to an example. Although the method 300 is explained with respect to memory dies, the method 300 may also be used to determine whether one or more planes of a particular memory die is failing or is likely to fail.

For example, a memory die may be identified as failing or likely to fail based on one or more performance characteristics of one or more voltage pumps that are shared across multiple planes of the memory die. However, a plane of the memory die may be identified as failing or likely to fail based on one or more performance characteristics of one or more voltage pumps that are associated with the plane of the memory die (e.g., voltage pumps that are not shared across the various planes of the memory die). In an example, the method 300 is performed by a memory die failure anticipation system of a data storage device such as, for example, the memory die failure anticipation system 180 shown and described with respect to FIG. 1.

In an example, the method 300 begins by tracking (310) a number of P/E cycles of a particular memory die (e.g., the first memory die 165 (FIG. 1)) of the data storage device. The memory die failure anticipation system then determines (320) whether a threshold number of P/E cycles has occurred.

In an example, the threshold number of P/E cycles is based, at least in part, on a desired frequency at which the memory die failure anticipation system will check whether a memory die is failing or is likely to fail. In an example, the threshold number of P/E cycles is one-thousand. In another example, the threshold number of P/E cycles is three-thousand. Although a specific number of P/E cycles is given, the threshold may be any number of P/E cycles.

If the memory die failure anticipation system determines (320) that the threshold number of P/E cycles has not been reached, the memory die failure anticipation system continues to track (310) the number of P/E cycles associated with memory die. However, if the memory die failure anticipation system determines (320) that the threshold number of P/E cycles has been met, the memory die failure anticipation system monitors or determines (330) a performance characteristic (or determines a first performance characteristic) of at least one voltage pump associated with the memory die at a first instance.

In an example, the first performance characteristic is a determination of a pump strength of at least one voltage pump that is associated with the memory die. Although a pump strength is specifically described, the first performance characteristic can be any measurable and/or determined metric (e.g., a pump rate) associated with a voltage pump and/or a memory die. In some examples, the first performance characteristic of the voltage pump is determined when the voltage pump is isolated from the memory cells of the memory die.

When the first performance characteristic is measured, the memory die failure anticipation system determines (340) whether the first performance characteristic exceeds a performance threshold. In an example, the performance threshold is a voltage is provided by the voltage pump, although other thresholds may be used.

If the memory die failure anticipation system determines that the first performance characteristic meets or exceeds the performance characteristic threshold, the method 300 is repeated. However, if the memory die failure anticipation system determines (340) that the first performance characteristic falls below the performance characteristic threshold, the memory die failure anticipation system determines whether the memory die is failing and/or is likely to fail.

To determine this, the memory die failure anticipation system monitors or determines (350) a performance characteristic (or determines a second performance characteristic) of the at least one voltage pump associated with the memory die at a second instance. In an example, the second instance is when the voltage pump is connected to the memory cells of the memory die.

The memory die failure anticipation system then determines (360) whether the first performance characteristic matches the second performance characteristics. For example and as previously described, if the first performance characteristic is a pump rate, the memory die failure anticipation system checks the pump rate of the voltage pump when the voltage pump is isolated from the memory cells (e.g., using a clock count method) and also checks the pump rate of the voltage pump when the voltage pump is connected to the memory cells. The memory die failure anticipation system then determines whether the total number of clock counts determined in the first instance matches the total number of clock counts determined in the second instance.

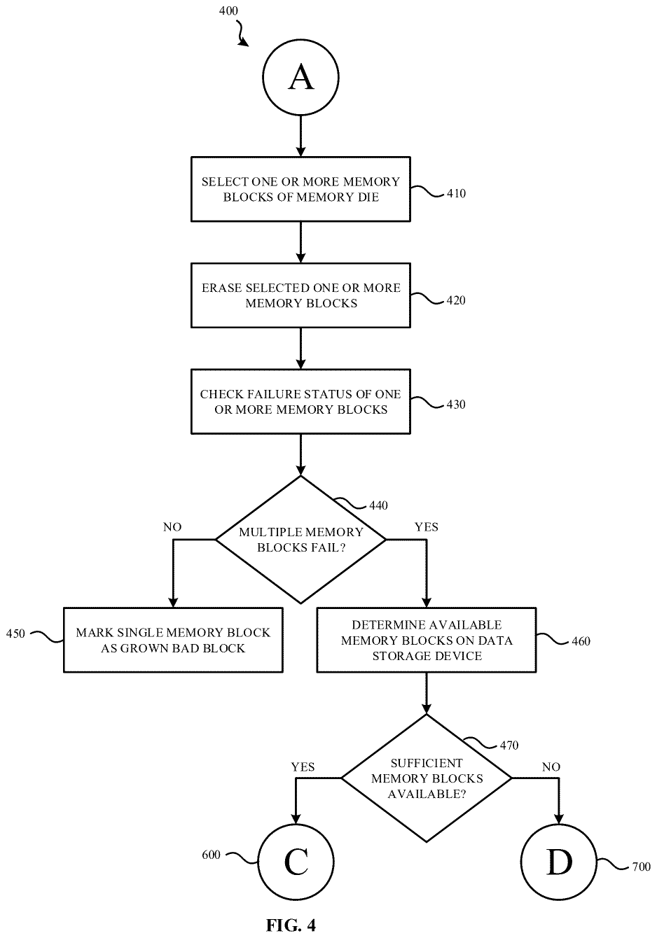

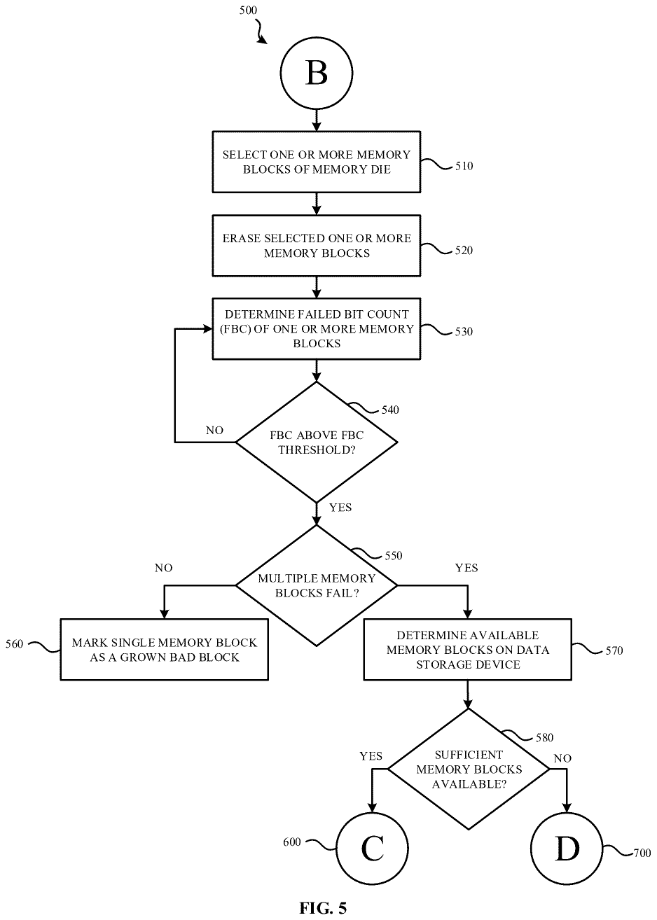

If the memory die failure anticipation system determines (360) that the first performance characteristic matches the second performance characteristic, a first memory die failure determination method (400) (indicated by the letter A) is initiated. However, if the memory die failure anticipation system determines (360) that the first performance characteristic does not match the second performance characteristic, a second memory die failure determination method (500), indicated by the letter B, is initiated. The first memory die failure determination method 400 will be described with respect to FIG. 4 and the second memory die failure determination method 500 will be described with respect to FIG. 5.

FIG. 4 illustrates a method 400 for determining whether a memory die is failing according to an example. In an example, the method 400 is executed by a memory die failure anticipation system of a data storage device, such as, for example, the memory die failure anticipation system 180 shown and described with respect to FIG. 1. In an example, the method 400 is also used to determine whether to initiate a relocation operation.

When determining whether to initiate the relocation operation, the memory die failure anticipation system selects (410) one or more memory blocks of the memory die that is being analyzed (e.g., the first memory die 165 (FIG. 1)). Each memory block is erased (420) and the memory die failure anticipation system checks and/or determines (430) the failure status of each of the one or more memory blocks such as previously described.

The memory die failure anticipation system then determines (440), based on the failure status, whether a single memory block has failed or whether multiple memory blocks have failed. If the memory die failure anticipation system determines (440) that a single memory block has failed, the memory die failure anticipation system marks (450) the single memory block as a grown bad block. The method 300 shown and described with respect to FIG. 3 may then be repeated.

However, if the memory die failure anticipation system determines (440) that multiple memory blocks have failed, the memory die failure anticipation system initiates either a first relocation operation or a second relocation operation. In an example, the determination as to which relocation operation is performed is based, at least in part, on a number of available memory blocks in the data storage device.

For example, the memory die failure anticipation system determines (460) the number and/or amount of available memory blocks on the data storage device. The memory die failure anticipation system then determines (470) whether the number of available memory blocks is sufficient. For example, the memory die failure anticipation system determines whether the amount of data that is to be relocated from the memory die can be stored by the number of available memory blocks.

If the memory die failure anticipation system determines (470) that there is a sufficient amount of available memory blocks and/or memory dies in the data storage device, the memory die failure anticipation system executes or initiates a first relocation operation 600 (indicated by the letter C) that will be shown and described with respect to FIG. 6. However, if the memory die failure anticipation system determines (470) that there is not a sufficient amount of available memory blocks, the memory die failure anticipation system executes or initiates a second relocation operation 700 (indicated by the letter D) that will be shown and described with respect to FIG. 7.

Referring back to FIG. 3 and as previously discussed, the memory die failure anticipation system may determine (360) that the first performance characteristic associated with the first instance do not match the second performance characteristic of the second instance. As such, the memory die failure anticipation system executes the method 500 shown and described with respect to FIG. 5.

FIG. 5 illustrates a method 500 for determining whether a memory die is failing according to another example. In an example, the method 500 is executed by a memory die failure anticipation system of a data storage device, such as, for example, the memory die failure anticipation system 180 shown and described with respect to FIG. 1. In an example, and like the method 400 shown and described with respect to FIG. 4, the method 500 is also used to determine whether to initiate a relocation operation.

When determining whether to initiate the relocation operation, the memory die failure anticipation system selects (510) one or more memory blocks across different planes of the particular memory die (e.g., the first memory die 165 (FIG. 1)) that is being analyzed. The memory die failure anticipation system erases (520) each of the selected memory blocks and determines a failed bit count (FBC) of each memory block. The memory die failure anticipation system then determines (540) whether the FBC of a particular memory block exceeds a FBC threshold. If the memory die failure anticipation system determines (540) that the FBC of the selected memory block does not exceed the FBC threshold, the next memory block is selected and the FBC of the selected memory block is determined (530). This process may be repeated for each selected memory block.

In an example, if the FBC of none of the selected memory blocks exceeds the FBC threshold, the method 500 ends. However, if the memory die failure anticipation system determines (540) that the FBC of one of the memory blocks exceeds the FBC threshold, the memory die failure anticipation system increases a voltage level (e.g., a read voltage and/or a program voltage) that is provided by the voltage pump associated with each memory block having a FBC over the FBC threshold.

If the FBC of a single memory block increases (but the FBC of the other selected memory blocks does not increase), the memory die failure anticipation system marks (560) that particular memory block as a grown bad block. The memory die failure anticipation system 180 may then repeat the method 300 shown and described with respect to FIG. 3.

However, if the memory die failure anticipation system determines (550) that the FBC of multiple memory blocks increases as the voltage increases, the memory die may be failing or may be likely to fail. As such, the memory die failure anticipation system initiates a relocation operation.

For example, the memory die failure anticipation system determines (570) the number and/or amount of available memory blocks on the data storage device. The memory die failure anticipation system then determines (580) whether the number of available memory blocks is sufficient. For example, the memory die failure anticipation system determines whether the amount of data that is to be relocated from the memory die can be stored by the number of available memory blocks.

If the memory die failure anticipation system determines (580) that there is a sufficient amount of available memory blocks, the memory die failure anticipation system executes or initiates a first relocation operation 600 (indicated by the letter C) that will be shown and described with respect to FIG. 6. However, if the memory die failure anticipation system determines (580) that there is not a sufficient amount of available memory blocks, the memory die failure anticipation system executes or initiates a second relocation operation 700 (indicated by the letter D) that will be shown and described with respect to FIG. 7.

FIG. 6 illustrates a first relocation operation 600 according to an example. In an example, the first relocation operation 600 is executed by a memory die failure anticipation system, such as, for example, the memory die failure anticipation system 160 shown and described with respect to FIG. 1. Additionally, and in an example, the first relocation operation is executed by the memory die failure anticipation system when the memory die failure anticipation system determines that the data storage device has a sufficient amount of available memory blocks.

The method 600 begins when the memory die failure anticipation system reads (610) data from the memory block(s) of the memory die that is failing or is likely to fail. Once the data has been read, the memory die failure anticipation system writes (620) the data to the available memory block(s).

In an example, the memory die failure anticipation system also changes and/or updates (630) one or more links (e.g., in a logical to physical mapping table) assoicated with the newly written memory blocks. For example, the memory die failure anticipation system relinks a pointer associated with the old memory blocks to point to the new memory blocks on which the data was written. The memory die failure anticipation system then marks (640) the memory blocks associated with the memory die as grown bad blocks.

FIG. 7 illustrates a second relocation operation 700 according to an example. In an example, the second relocation operation 700 is executed by a memory die failure anticipation system, such as, for example, the memory die failure anticipation system 160 shown and described with respect to FIG. 1. Additionally, and in an example, the second relocation operation is executed by the memory die failure anticipation system when the memory die failure anticipation system determines that the data storage device does not have a sufficient amount of available memory blocks for the relocation operation.

The method 700 begins when the memory die failure anticipation system reads (710) data from the memory block(s) of the memory die that is failing or is likely to fail. Once the data has been read, the memory die failure anticipation system writes (720) the data to the available memory block(s). In an example, the memory die failure anticipation system writes the data into any and/or all available SLC memory blocks. However, in some examples, the memory die failure anticipation system causes the SLC memory blocks to operate in MLC mode.

In an example, the memory die failure anticipation system also changes and/or updates (730) one or more links (e.g., in a logical to physical mapping table) assoicated with the newly written memory blocks. For example, the memory die failure anticipation system relinks a pointer associated with the old memory blocks to point to the new memory blocks on which the data was written.

The memory die failure anticipation system then marks (740) the memory blocks associated with the memory die as grown bad blocks. The memory die failure anticipation system may also cause the data storage device to enter (750) a read-only mode. In an example, the memory die failure anticipation system causes the data storage device to enter the read-only mode when the second relocation operation exhausts all of the SLC memory blocks.

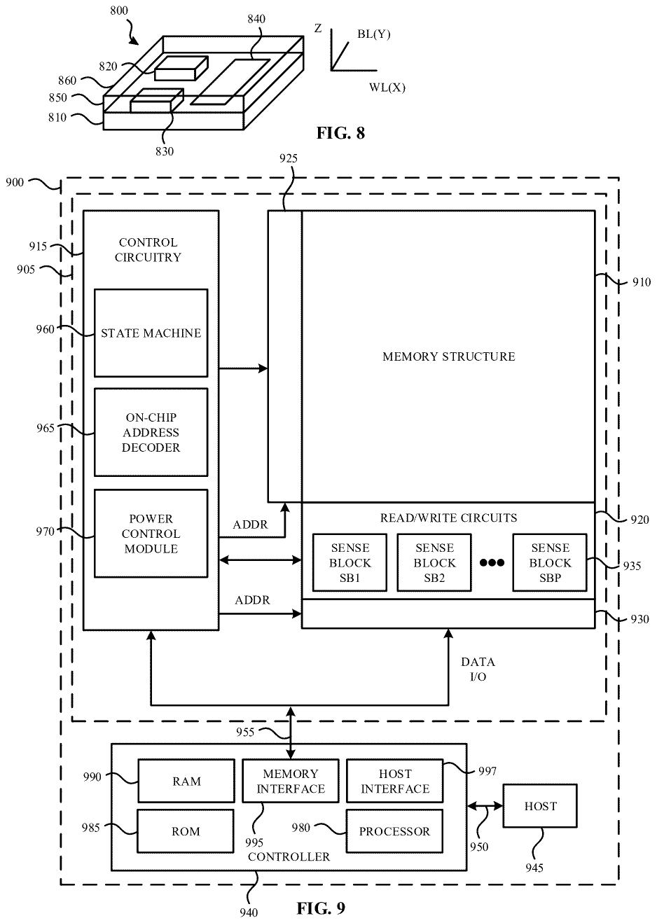

FIG. 8-FIG. 9 describe example storage devices that may be used with or otherwise implement the various features described herein. For example, the storage devices shown and described with respect to FIG. 8-FIG. 9 may include various systems and components that are similar to the systems and components shown and described with respect to FIG. 1. For example, the controller 922 shown and described with respect to FIG. 9 may be similar to the controller 150 of FIG. 1. Likewise, the memory dies 908 may be similar to the first memory die 165 and/or the second memory die 170 of FIG. 1.

FIG. 8 is a perspective view of a storage device 800 that includes three-dimensional (3D) stacked non-volatile memory according to an example. In this example, the storage device 800 includes a substrate 810. Blocks of memory cells are included on or above the substrate 810. The blocks include a first block (BLK0 820) and a second block (BLK1 830). Each block is formed of memory cells (e.g., non-volatile memory elements). The substrate 810 also includes a peripheral area 840 having support circuits that are used by the first block and the second block.

The substrate 810 also carries circuits under the blocks, along with one or more lower metal layers which are patterned in conductive paths to carry signals from the circuits. In an example, the blocks are formed in an intermediate region 850 of the storage device 800. The storage device also includes an upper region 860. The upper region 860 includes one or more upper metal layers that are patterned in conductive paths to carry signals from the circuits. Each block of memory cells includes a stacked area of memory cells. In an example, alternating levels of the stack represent wordlines. While two blocks are depicted, additional blocks may be used and extend in the x-direction and/or the y-direction.

In an example, a length of a plane of the substrate 810 in the x-direction represents a direction in which signal paths for wordlines or control gate lines extend (e.g., a wordline or drain-end select gate (SGD) line direction) and the width of the plane of the substrate 810 in the y-direction represents a direction in which signal paths for bit lines extend (e.g., a bit line direction). The z-direction represents a height of the storage device 800.

FIG. 9 is a functional block diagram of a storage device 900 according to an example. In an example, the storage device 900 is similar to the 3D stacked non-volatile storage device 800 shown and described with respect to FIG. 8. In an example, the components depicted in FIG. 9 are electrical circuits. In an example, the storage device 900 includes one or more memory dies 905. Each memory die 905 includes a three-dimensional memory structure 910 of memory cells (e.g., a 3D array of memory cells), control circuitry 915, and read/write circuits 920. In another example, a two-dimensional array of memory cells may be used. The memory structure 910 is addressable by wordlines using a first decoder 925 (e.g., a row decoder) and by bit lines using a second decoder 930 (e.g., a column decoder). The read/write circuits 920 may also include multiple sense blocks 935 including SB1, SB2, . . . , SBp (e.g., sensing circuitry) which allow pages of the memory cells to be read or programmed in parallel. The sense blocks 935 may include bit line drivers.

In an example, a controller 940 is included in the same storage device 900 as the one or more memory dies 905. In another example, the controller 940 is formed on a die that is bonded to a memory die 905, in which case each memory die 905 may have its own controller 940. In yet another example, a controller die controls all of the memory dies 905. Although a single controller 940 is shown, the storage device 900 can include multiple controllers with each controller responsible for different operations described herein.

Commands and data are transferred between a host 945 and the controller 940 using a data bus 950. Additionally, commands and data are transferred between the controller 940 and one or more of the memory dies 905 by way of lines 955. In one example, the memory die 905 includes a set of input and/or output (I/O) pins that connect to lines 955.

The memory structure 910 also includes one or more arrays of memory cells. The memory cells are arranged in a three-dimensional array or a two-dimensional array. The memory structure 910 includes any type of non-volatile memory that is formed on one or more physical levels of arrays of memory cells having an active area disposed above a silicon substrate. The memory structure 910 may be in a non-volatile memory device having circuitry associated with the operation of the memory cells, whether the associated circuitry is above or within the substrate.

The control circuitry 915 works in conjunction with the read/write circuits 920 to perform memory operations (e.g., erase, program, read, and others) on the memory structure 910. The control circuitry 915 may include registers, ROM fuses, and other devices for storing default values such as base voltages and other parameters.

The control circuitry 915 also includes a state machine 960, an on-chip address decoder 965 and a power control module. The state machine 960 provides chip-level control of various memory operations, such as selecting a memory block for programming. The state machine 960 is programmable by software. In another example, the state machine 960 does not use software and is completely implemented in hardware (e.g., electrical circuits).

The on-chip address decoder 965 provides an address interface between addresses used by host 945 and/or the controller 940 to a hardware address used by the first decoder 925 and the second decoder 930. The power control module 970 controls power and voltages that are supplied to the wordlines and bit lines during memory operations. The power control module 970 may include drivers for wordline layers in a 3D configuration, select gate transistors (e.g., SGS and SGD transistors) and source lines. The power control module 970 may include one or more charge pumps for creating voltages. In an example, the power control module 970 helps ensure wordlines of the grown bad block described herein are programmed at the desired levels.

The control circuitry 915, the state machine 960, the on-chip address decoder 965, the first decoder 925, the second decoder 930, the power control module 970, the sense blocks 935, the read/write circuits 920, and/or the controller 940 may be considered one or more control circuits and/or a managing circuit that perform some or all of the operations described herein.

In an example, the controller 940, is an electrical circuit that may be on-chip or off-chip. Additionally, the controller 940 may include one or more processors 980, ROM 985, RAM 990, memory interface 995, and host interface 997, all of which may be interconnected. In an example, the one or more processors 980 is one example of a control circuit. Other examples can use state machines or other custom circuits designed to perform one or more functions. Devices such as ROM 985 and RAM 990 may include code such as a set of instructions. One or more of the processors 980 may be operable to execute the set of instructions to provide some or all of the functionality described herein.

Alternatively or additionally, one or more of the processors 980 may access code from a memory device in the memory structure 910, such as a reserved area of memory cells connected to one or more wordlines. The memory interface 995, in communication with ROM 985, RAM 990, and one or more of the processors 980, may be an electrical circuit that provides an electrical interface between the controller 940 and the memory die 905. For example, the memory interface 995 may change the format or timing of signals, provide a buffer, isolate from surges, latch I/O, and so forth.

The one or more processors 980 may issue commands to control circuitry 915, or any other component of memory die 905, using the memory interface 995. The host interface 997, in communication with the ROM 985, the RAM 990, and the one or more processors 980, may be an electrical circuit that provides an electrical interface between the controller 940 and the host 945. For example, the host interface 997 may change the format or timing of signals, provide a buffer, isolate from surges, latch I/O, and so on. Commands and data from the host 945 are received by the controller 940 by way of the host interface 997. Data sent to the host 945 may be transmitted using the data bus 950.

Multiple memory elements in the memory structure 910 may be configured so that they are connected in series or so that each element is individually accessible. By way of a non-limiting example, flash memory devices in a NAND configuration (e.g., NAND flash memory) typically contain memory elements connected in series. A NAND string is an example of a set of series-connected memory cells and select gate transistors.

A NAND flash memory array may also be configured so that the array includes multiple NAND strings. In an example, a NAND string includes multiple memory cells sharing a single bit line and are accessed as a group. Alternatively, memory elements may be configured so that each memory element is individually accessible (e.g., a NOR memory array). The NAND and NOR memory configurations are examples and memory cells may have other configurations.

The memory cells may be arranged in the single memory device level in an ordered array, such as in a plurality of rows and/or columns. However, the memory elements may be arrayed in non-regular or non-orthogonal configurations, or in structures not considered arrays.

In an example, a 3D memory structure may be vertically arranged as a stack of multiple 2D memory device levels. As another non-limiting example, a 3D memory array may be arranged as multiple vertical columns (e.g., columns extending substantially perpendicular to the major surface of the substrate, such as in the y direction) with each column having multiple memory cells. The vertical columns may be arranged in a two-dimensional arrangement of memory cells, with memory cells on multiple vertically stacked memory planes. Other configurations of memory elements in three dimensions can also constitute a 3D memory array.

In another example, in a 3D NAND memory array, the memory elements may be coupled together to form vertical NAND strings that traverse across multiple horizontal memory device levels. Other 3D configurations can be envisioned wherein some NAND strings contain memory elements in a single memory level while other strings contain memory elements which span through multiple memory levels. 3D memory arrays may also be designed in a NOR configuration and in a ReRAM configuration.

Based on the above, examples of the present disclosure describe a method, comprising: determining at least one performance characteristic of at least one voltage pump of a memory device at a first instance; comparing the at least one performance characteristic of the at least one voltage pump of the memory device to a performance characteristic threshold; based, at least in part, on determining the at least one performance characteristic of the at least one voltage pump of the memory device is below the performance characteristic threshold, determining the at least one performance characteristic of the at least one voltage pump of the memory device at a second instance; comparing the performance characteristic of the at least one voltage pump of the memory device at the first instance to the performance characteristic of the at least one voltage pump of the memory device at the second instance; and based, at least in part, on the performance characteristic of the at least one voltage pump of the memory device at the first instance matching the performance characteristic of the at least one voltage pump of the memory device at the second instance: selecting a plurality of memory blocks of the memory device associated with the at least one voltage pump; erasing each memory block of the plurality of memory blocks; determining a status of each memory block of the plurality of memory blocks; and determining whether to initiate a relocation operation based, at least in part, on the determined status of each memory block of the plurality of memory blocks. In an example, the relocation operation is initiated based, at least in part, on multiple memory blocks of the plurality of memory blocks having a failed status. In an example, the method also includes identifying a number of free memory blocks in the memory device; and proceeding with the relocation operation using a first relocation methodology based, at least in part, on the number of free memory blocks in the memory device exceeding a free memory block threshold. In an example, the first methodology comprises: reading data from memory blocks associated with the plurality of memory blocks having the failed status; writing the data from the memory blocks associated with the plurality of memory blocks having the failed status to the free memory blocks in the memory device; updating a mapping table associated with the memory blocks; and marking the memory blocks associated with the plurality of memory blocks having the failed status, and the memory blocks having the failed status as grown bad blocks. In an example, the method also includes proceeding with the relocation operation using a second relocation methodology based, at least in part, on the number of free memory blocks in the memory device falling below the free memory block threshold. In an example, the second methodology comprises: reading data from memory blocks associated with the plurality of memory blocks having the failed status; writing the data from the memory blocks associated with the plurality of memory blocks having the failed status to the free memory blocks in the memory device, at least one of the free memory blocks having been switched from a first mode to a second mode; updating a mapping table associated with the memory blocks; and marking the memory device as a read only memory device. In an example, the first mode is a single-level cell (SLC) mode and wherein the second mode is a multi-level cell (MLC) mode. In an example, the method also includes marking a single memory block of the plurality of memory blocks as a grown bad block based, at least in part, on the determined status of the single memory block. In an example, the method also includes checking a failed bit count of a plurality of memory blocks of the memory device associated with the at least one voltage pump based, at least in part, on the performance characteristic of the at least one voltage pump of the memory device at the first instance being different from the performance characteristic of the at least one voltage pump of the memory device at the second instance. In an example, the method also includes determining whether to initiate a relocation operation based, at least in part, on the failed bit count of the plurality of memory blocks exceeding a failed bit count threshold.

Examples also describe a memory device, comprising: a controller; and a memory die failure anticipation system communicatively coupled to the controller and operable to: periodically determine a first performance characteristic of at least one voltage pump associated with the memory device; initiate a first memory die failure anticipation operation based, at least in part, on the first performance characteristic matching a second performance characteristic of the at least one voltage pump associated with the memory device; and initiate a second memory die failure anticipation operation based, at least in part, on the first performance characteristic being different than the second performance characteristic. In an example, the memory die failure anticipation system determines the first performance characteristic of the at least one voltage pump associated with the memory device when a threshold number of program/erase cycles have been executed by the memory device. In an example, the first performance characteristic of the at least one voltage pump is an output voltage of the at least one voltage pump. In an example, the first performance characteristic of the at least one voltage pump is a pump rate of the at least one voltage pump. In an example, the at least one voltage pump is associated with a plane of a memory die of the memory device. In an example, the at least one voltage pump is associated with a memory die of the memory device. In an example, the first memory die failure anticipation operation comprises: determining whether multiple memory blocks associated with the at least one voltage pump have failed; determining whether a number of free memory blocks in the memory device exceed a free memory block threshold; and based, at least in part on determining multiple memory blocks associated with the at least one voltage pump have failed and the number of free memory blocks in the memory device exceed a free memory block threshold: writing data from the memory blocks associated with the plurality of memory blocks having a failed status to the free memory blocks in the memory device; updating a mapping table associated with the memory blocks; and marking the memory blocks associated with the plurality of memory blocks having the failed status, and the memory blocks having the failed status as grown bad blocks. In an example, the second memory die failure anticipation operation comprises: determining whether multiple memory blocks associated with the at least one voltage pump have failed; based, at least in part, on determining the multiple memory blocks associated with the at least one voltage pump have failed: determining a failed bit count associated with each memory block of the multiple memory blocks; increasing a voltage that is applied to each memory block of the multiple memory blocks; determining whether the failed bit count associated with each memory block of the multiple memory blocks has increased; and
marking at least a portion of the memory die associated with the each memory block of the multiple memory blocks as failed.

Examples also describe a memory device, comprising: means for determining a performance characteristic of at least one voltage supply means associated with the memory device; means for comparing the performance characteristic of the at least one voltage supply means to a performance characteristic threshold; means for determining whether multiple memory blocks associated with the voltage supply means have failed, wherein the means for determining whether the multiple memory blocks associated with the voltage supply means has failed makes the determination based, at least in part, on the comparing the performance characteristic of the at least one voltage supply means to the performance characteristic threshold; and means for initiating a relocation operation, wherein the means for initiating the relocation operation initiates the relocation operation based, at least in part, on the means for determining whether multiple memory blocks associated with the voltage supply means determines that multiple memory blocks have failed. In an example, the memory device also includes means for marking a single memory block of the multiple memory blocks as a grown bad block, wherein the means for marking the single memory block of the multiple memory blocks as a grown bad block marks the single memory block as a grown bad block based, at least in part, on the means for determining whether the multiple memory blocks associated with the voltage supply means have failed determines a single memory block has failed.

One of ordinary skill in the art will recognize that the technology described herein is not limited to a single specific memory structure, but covers many relevant memory structures within the spirit and scope of the technology as described herein and as understood by one of ordinary skill in the art.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an example with a particular set of features. Having been provided with the description and illustration of the present disclosure, one skilled in the art may envision variations, modifications, and alternate aspects falling within the spirit of the broader aspects of the general inventive concept embodied in this disclosure that do not depart from the broader scope of the claimed disclosure.

Aspects of the present disclosure have been described above with reference to schematic flowchart diagrams and/or schematic block diagrams of methods, apparatuses, systems, and computer program products according to examples of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method, comprising:
determining at least one performance characteristic of at least one voltage pump of a memory device at a first instance;
comparing the at least one performance characteristic of the at least one voltage pump of the memory device to a performance characteristic threshold;
based, at least in part, on determining the at least one performance characteristic of the at least one voltage pump of the memory device is below the performance characteristic threshold, determining the at least one performance characteristic of the at least one voltage pump of the memory device at a second instance;
comparing the performance characteristic of the at least one voltage pump of the memory device at the first instance to the performance characteristic of the at least one voltage pump of the memory device at the second instance; and
based, at least in part, on the performance characteristic of the at least one voltage pump of the memory device at the first instance matching the performance characteristic of the at least one voltage pump of the memory device at the second instance:
selecting a plurality of memory blocks of the memory device associated with the at least one voltage pump;
erasing each memory block of the plurality of memory blocks;
determining a status of each memory block of the plurality of memory blocks; and
determining whether to initiate a relocation operation based, at least in part, on the determined status of each memory block of the plurality of memory blocks.

2. The method of claim 1, wherein the relocation operation is initiated based, at least in part, on multiple memory blocks of the plurality of memory blocks having a failed status.

3. The method of claim 2, further comprising:
identifying a number of free memory blocks in the memory device; and
proceeding with the relocation operation using a first relocation methodology based, at least in part, on the number of free memory blocks in the memory device exceeding a free memory block threshold.

4. The method of claim 3, wherein the first methodology comprises:
reading data from memory blocks associated with the plurality of memory blocks having the failed status;
writing the data from the memory blocks associated with the plurality of memory blocks having the failed status to the free memory blocks in the memory device;
updating a mapping table associated with the memory blocks; and
marking the memory blocks associated with the plurality of memory blocks having the failed status, and the memory blocks having the failed status as grown bad blocks.

5. The method of claim 3, further comprising proceeding with the relocation operation using a second relocation methodology based, at least in part, on the number of free memory blocks in the memory device falling below the free memory block threshold.

6. The method of claim 5, wherein the second methodology comprises:
reading data from memory blocks associated with the plurality of memory blocks having the failed status;
writing the data from the memory blocks associated with the plurality of memory blocks having the failed status to the free memory blocks in the memory device, at least one of the free memory blocks having been switched from a first mode to a second mode;
updating a mapping table associated with the memory blocks; and
marking the memory device as a read only memory device.

7. The method of claim 6, wherein the first mode is a single-level cell (SLC) mode and wherein the second mode is a multi-level cell (MLC) mode.

8. The method of claim 1, further comprising marking a single memory block of the plurality of memory blocks as a grown bad block based, at least in part, on the determined status of the single memory block.

9. The method of claim 1, further comprising checking a failed bit count of a plurality of memory blocks of the memory device associated with the at least one voltage pump based, at least in part, on the performance characteristic of the at least one voltage pump of the memory device at the first instance being different from the performance characteristic of the at least one voltage pump of the memory device at the second instance.

10. The method of claim 9, further comprising determining whether to initiate a relocation operation based, at least in part, on the failed bit count of the plurality of memory blocks exceeding a failed bit count threshold.

11. A memory device, comprising:
a controller; and
a memory die failure anticipation system communicatively coupled to the controller and operable to:
periodically determine a first performance characteristic of at least one voltage pump associated with the memory device;
initiate a first memory die failure anticipation operation based, at least in part, on the first performance characteristic matching a second performance characteristic of the at least one voltage pump associated with the memory device; and
initiate a second memory die failure anticipation operation based, at least in part, on the first performance characteristic being different than the second performance characteristic.

12. The memory device of claim 11, wherein the memory die failure anticipation system determines the first performance characteristic of the at least one voltage pump associated with the memory device when a threshold number of program/erase cycles have been executed by the memory device.

13. The memory device of claim 11, wherein the first performance characteristic of the at least one voltage pump is an output voltage of the at least one voltage pump.

14. The memory device of claim 11, wherein the first performance characteristic of the at least one voltage pump is a pump rate of the at least one voltage pump.

15. The memory device of claim 11, wherein the at least one voltage pump is associated with a plane of a memory die of the memory device.

16. The memory device of claim 11, wherein the at least one voltage pump is associated with a memory die of the memory device.

17. The memory device of claim 11, wherein the first memory die failure anticipation operation comprises:
determining whether multiple memory blocks associated with the at least one voltage pump have failed;
determining whether a number of free memory blocks in the memory device exceed a free memory block threshold; and
based, at least in part on determining multiple memory blocks associated with the at least one voltage pump have failed and the number of free memory blocks in the memory device exceed a free memory block threshold:
writing data from the memory blocks associated with the plurality of memory blocks having a failed status to the free memory blocks in the memory device;
updating a mapping table associated with the memory blocks; and
marking the memory blocks associated with the plurality of memory blocks having the failed status, and the memory blocks having the failed status as grown bad blocks.

18. The memory device of claim 11, wherein the second memory die failure anticipation operation comprises:
determining whether multiple memory blocks associated with the at least one voltage pump have failed;
based, at least in part, on determining the multiple memory blocks associated with the at least one voltage pump have failed:
determining a failed bit count associated with each memory block of the multiple memory blocks;
increasing a voltage that is applied to each memory block of the multiple memory blocks;
determining whether the failed bit count associated with each memory block of the multiple memory blocks has increased; and
marking at least a portion of the memory die associated with the each memory block of the multiple memory blocks as failed.

19. A memory device, comprising:
means for determining a performance characteristic of at least one voltage supply means associated with the memory device;
means for comparing the performance characteristic of the at least one voltage supply means to a performance characteristic threshold;
means for determining whether multiple memory blocks associated with the voltage supply means have failed, wherein the means for determining whether the multiple memory blocks associated with the voltage supply means has failed makes the determination based, at least in part, on the comparing the performance characteristic of the at least one voltage supply means to the performance characteristic threshold; and
means for initiating a relocation operation, wherein the means for initiating the relocation operation initiates the relocation operation based, at least in part, on the means for determining whether multiple memory blocks associated with the voltage supply means determines that multiple memory blocks have failed.

20. The memory device of claim 19, further comprising means for marking a single memory block of the multiple memory blocks as a grown bad block, wherein the means for marking the single memory block of the multiple memory blocks as a grown bad block marks the single memory block as a grown bad block based, at least in part, on the means for determining whether the multiple memory blocks associated with the voltage supply means have failed determines a single memory block has failed.
